(19) United States
(12) Patent Application Publication
(10) Pub. No.: US 2026/0235407 A1
(43) Pub. Date: Aug. 13, 2026

(54) CARRYING APPARATUS FOR CARRYING A MEMS SENSOR

(71) Applicant: Northrop Grumman Litef GmbH, Freiburg (DE)

(72) Inventor: Johannes PFEIFFER, Bahlingen am Kaiserstuhl (DE)

(21) Appl. No.: 19/153,656

(22) PCT Filed: Oct. 18, 2023
(86) PCT No.: PCT/EP2023/078995

§ 371 Date: Aug. 5, 2025

(30) Foreign Application Priority Data
Feb. 8, 2023 (DE) 10 2023 103 045.0

(51) Int. Cl. G01C 19/5712

(52) U.S. Cl. CPC G01C 19/5712

(57) ABSTRACT

A carrying apparatus (100) for carrying a microelectromechanical (MEMS) sensor (200) has a carrier platform (110) which is suitable for carrying the MEMS sensor (200), and a coupling structure (120) which has individual, macroscopic springs (130), connected to the carrier platform (110), and which is suitable for being connected to a housing structure (300), wherein the housing structure (300) is suitable for enclosing the carrying apparatus (100) and the MEMS sensor (200) carried by said carrying apparatus.

The present invention relates to a carrying apparatus for carrying a microelectromechanical, MEMS, sensor and to a sensor having such a carrying apparatus.

MEMS sensors are nowadays used in many areas of technology. MEMS sensors are particularly suitable as acceleration and/or rotation rate sensors. The MEMS sensor is typically enclosed by a housing to prevent direct impacts on the MEMS sensor. However, the housing itself can vibrate or be exposed to shocks. In addition, it can change its shape due to temperature fluctuations, for example.

In this case, the quality of the measurement data output by the sensors depends not least on how well the MEMS sensor can be decoupled from vibrations of the housing, force impacts on the housing, or deformations of the housing. The MEMS sensor will supply more reliable measurement results, the less its position is changed by such movements of the housing and the less mechanical stress, for example, due to thermal deformations, from the surrounding environment acts on the sensor.

To this end, mechanisms are used to decouple the movement/deformation of the housing from the movement/deformation of the MEMS sensor. For example, micromechanical structures that cushion and/or dampen movements of the housing relative to the MEMS sensor are known here (cf., for example, US 2018/252739A1). Likewise, it is known to insert elastomers between the MEMS sensor and the housing in order to dampen movements of the housing relative to the MEMS sensor (cf. US 2008/264169A1).

However, such mechanisms have disadvantages. The implementation of a decoupling by means of micromechanical structures usually does not enable a direct (and detachable) connection to the system housing, which is why a further, usually complex joining process is necessary here to connect the decoupling structure to the system housing. The material properties of elastomers can change depending on the temperature or aging of the material. On one hand, this can change the operating conditions for the MEMS sensor. On the other hand, the ability to decouple the MEMS sensor from external movements can also be lost as a result.

Both micromechanical structures and elastomers cannot be easily removed from the sensor and replaced, e.g., in case of a defect or malfunction, or prevent the replacement of other defective components. In case of micromechanical structures, this is due to the fact that they are permanently installed with the sensor. When elastomers are used, this difficulty results from the fact that the elastomers are connected to the other components in a material-to-material bond. This makes it necessary to first dissolve the existing connections and then rejoin them, which is very time-consuming.

It is therefore the object of the present invention to indicate an apparatus for carrying a MEMS sensor, which reliably and simply decouples the MEMS sensor from movements and/or deformations of neighboring components. Furthermore, it is the object of the present invention to indicate a sensor, which includes the apparatus for carrying a MEMS sensor and the MEMS sensor.

These objects are achieved by the subject matter of the independent claims.

A carrying apparatus for carrying a microelectromechanical, MEMS, sensor has a carrier platform, which is suitable for carrying the MEMS sensor and includes a coupling structure, which has individual, macroscopic springs connected to the carrier platform, and which is suitable for being connected to a housing structure, wherein the housing structure is suitable for enclosing the carrying apparatus and the MEMS sensor carried by said carrying apparatus.

The carrying apparatus is therefore suitable for connecting a MEMS sensor, which is attached to the carrier platform, to a housing structure or a housing of the overall sensor. For this purpose, the carrying apparatus has macroscopic springs, i.e., no micromechanical springs, as, for example, known from US 2018/252739A1, and also no elastomer couplings, as, for example, described in US 2008/264169A1. The macroscopic springs are, in this case, suitable for supporting the carrier platform relative to the housing structure and absorbing movements and deformations of the housing structure, so that the carrier platform—and with it the MEMS sensor—remains sufficiently at rest and undeformed for reliable operation. As the springs are of macroscopic design, e.g., in case of bending beams with a material thickness of at least 0.3 mm, it is possible to manufacture them comparatively easily, in particular using common macroscopic fabrication processes such as machining, eroding and the like. In addition, the use of mechanical springs instead of elastomers prevents the occurrence of fluctuations in the coupling properties of the carrying apparatus due to aging or temperature dependence.

The use of a carrying apparatus with macroscopic springs thus makes it possible to decouple a MEMS sensor from the movements of the surrounding components in a simple and reliable manner.

In this process, at least the springs, preferably the entire coupling structure, can be made of a metal. On one hand, this simplifies fabrication, as the manufacture of metal structures is comparatively simple. In addition, metal springs make it possible to achieve low self-damping, whereby movements in the surrounding environment are better absorbed by the springs. As a result, the decoupling of the carrier platform carrying the MEMS sensor from such movements is improved, which, in turn, increases the reliability of the MEMS sensor's measurement data. Low self-damping generally also results in vibrations of the carrying apparatus in the range of the typical operating frequencies of the MEMS sensor being suppressed/insulated to a greater extent than with a comparable carrying apparatus with greater self-damping (for example, due to an elastomer).

The coupling structure can be suitable for being connected to the housing structure by means of screw connections. As the coupling structure and, in particular, the springs are of macroscopic design, they can be easily attached by means of screw connections. This further simplifies manufacture. In addition, the screw connections can also be easily loosened again, making it easier to replace the carrying apparatus or the coupling structure and the MEMS sensor attached thereto.

The coupling structure can be suitable for thermally insulating the MEMS sensor and the housing structure from each other, preferably in that the springs have a small cross section compared to their length, and the springs are the only continuous connection consisting of one material between the housing structure and the carrier platform and/or in that the thermal mass of the coupling structure is less than the thermal mass of the carrier platform. External temperature fluctuations therefore only reach the MEMS sensor in a highly damped form or not at all. In any case, the MEMS sensor will only change its temperature very slowly and evenly. This improves the reliability of the sensor data.

The carrier platform can be designed as a plate and the springs formed as pairs of bending beam springs, wherein the bending beam springs of a pair are connected to a point on the circumference of the plate at their first end and to each other at their second end, and each bending beam spring is curved in such a way that there is an interspace between each pair of bending beam springs. The pairs of bending beam springs can then each be connected to the housing structure via their second end, preferably by means of screw connections. As a result, a specific embodiment of the carrying apparatus is provided.

A sensor apparatus has a MEMS sensor, a carrying apparatus as described above, wherein the MEMS sensor is attached to the carrier platform of the carrying apparatus, and a housing structure, which encloses the carrying apparatus and the MEMS sensor carried thereon and which is connected to the MEMS sensor via the coupling structure of the carrying apparatus. As a result, a sensor apparatus is indicated, which has a MEMS sensor that is decoupled from movements of the sensor in a simple and reliable manner.

In this case, the coefficients of thermal expansion of at least two interconnected elements from the list of springs, carrier platform, MEMS sensor can be matched to each other and preferably have a deviation of less than 300%, 200%, 100% or 50% from each other. This allows reducing or eliminating deformations due to different length expansions in case of temperature changes. In particular, an advantage can be achieved here compared to sensors that use elastomers or silicones for decoupling, since these materials typically have coefficients of thermal expansion that cannot be reconciled with the coefficients of thermal expansion of the materials from which MEMS sensors are made, in particular not with the coefficient of thermal expansion of silicon.

In particular, the springs and the carrier platform can be made of the same material, the coefficient of thermal expansion of which is adapted to the material of the MEMS sensor or its packaging. Alternatively or additionally, the material of the carrier platform can be Kovar (material No. 1.3981, e.g., 54% iron, 29% nickel, 17% cobalt) or similar if the MEMS sensor was manufactured on a silicon basis.

The natural frequency of the carrying apparatus with the MEMS sensor attached thereto can be greater than the bandwidth of the MEMS sensor and less than the drive frequency of the MEMS sensor. This means that the carrying apparatus together with the MEMS sensor per-forms natural vibrations at frequencies that differ both from the operating frequency with which the MEMS sensor is excited and from the bandwidth of the MEMS sensor, which indicates the frequency range in which the MEMS sensor can measure. The operating frequency, in this case, can lie in the range of 10kHz, while the bandwidth can be 10 to 100 Hz, for example. As a result, it can be ensured that the natural vibrations of the carrying apparatus do not interfere with the operation of the MEMS sensor. The natural frequency of the carrying apparatus with the MEMS sensor can, in this case, be determined in a manner known per se by the design of the carrying apparatus.

The carrying apparatus can have a resonant frequency that is identical in all three spatial directions. As a result, the MEMS sensor can be decoupled equally well from external movements in all spatial directions. The identical resonant frequencies, for example, can be achieved by a carrying apparatus that is symmetrical in design in two dimensions and is structured in such a way that its main moments of inertia are in agreement.

The carrying apparatus can be suitable for preventing transmission of deformations of the housing structure, in particular due to temperature changes, to the MEMS sensor. Such deformations are primarily absorbed by the springs and, as a result, are not passed on to the carrier platform and the MEMS sensor. As a result, the reliability of the sensor apparatus is increased, since the operation of the MEMS sensor is not disturbed by deformations of the housing.

The present invention will be further described in the following text, with reference to the figures. The following description is purely exemplary and may not be understood as being re-strictive. The present invention is defined solely by the subject matter of the claims.

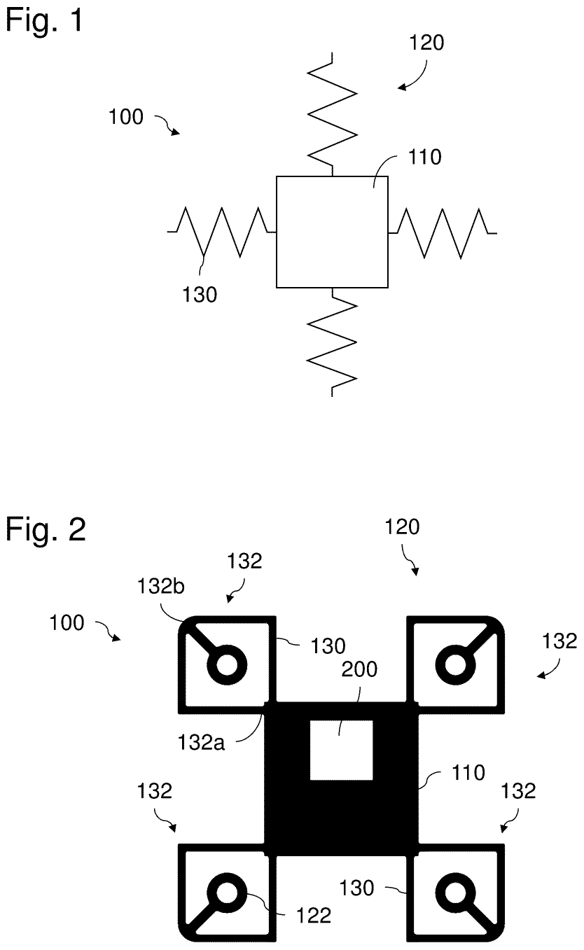

FIG. 1 shows a schematic representation of a carrying apparatus for a MEMS sensor;

FIG. 2 shows a schematic representation of another carrying apparatus for a MEMS sensor;

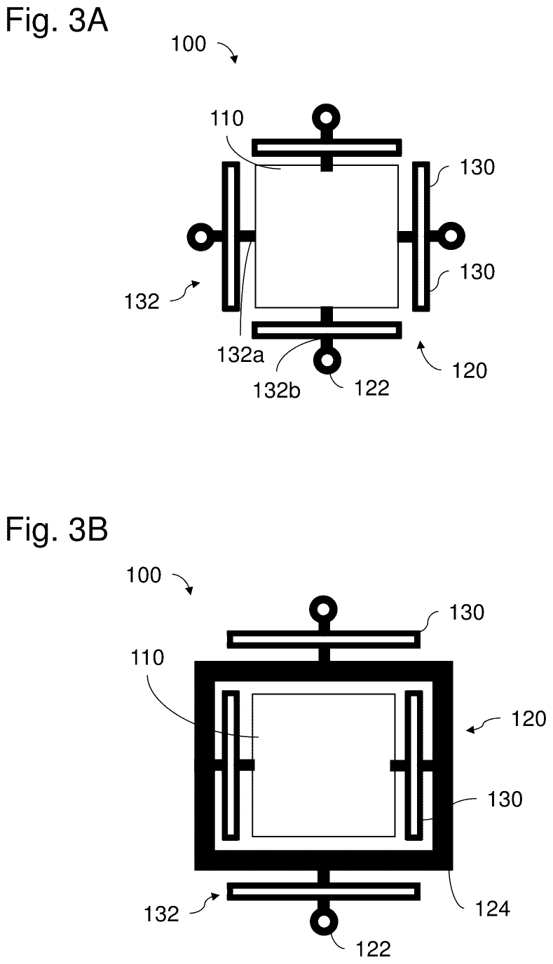

FIGS. 3A and 3B show schematic representations of additional carrying apparatuses for a MEMS sensor;

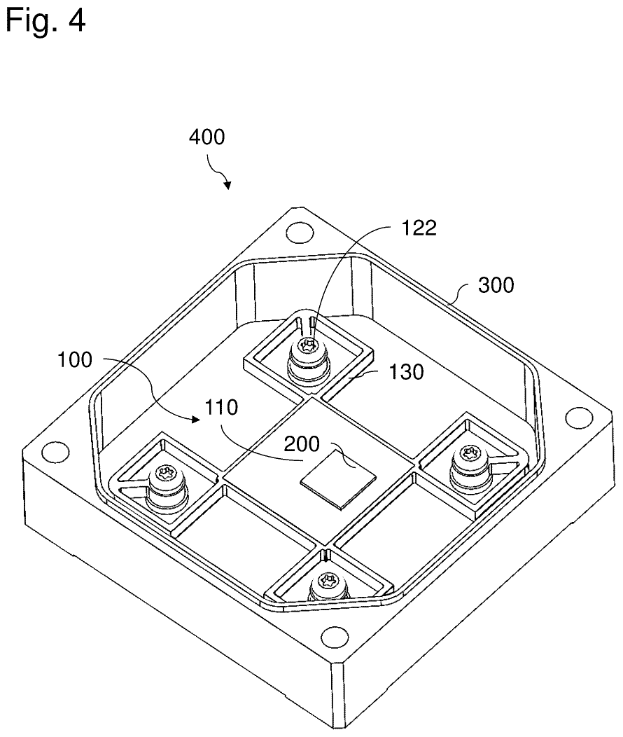

FIG. 4 shows a schematic representation of a sensor apparatus;

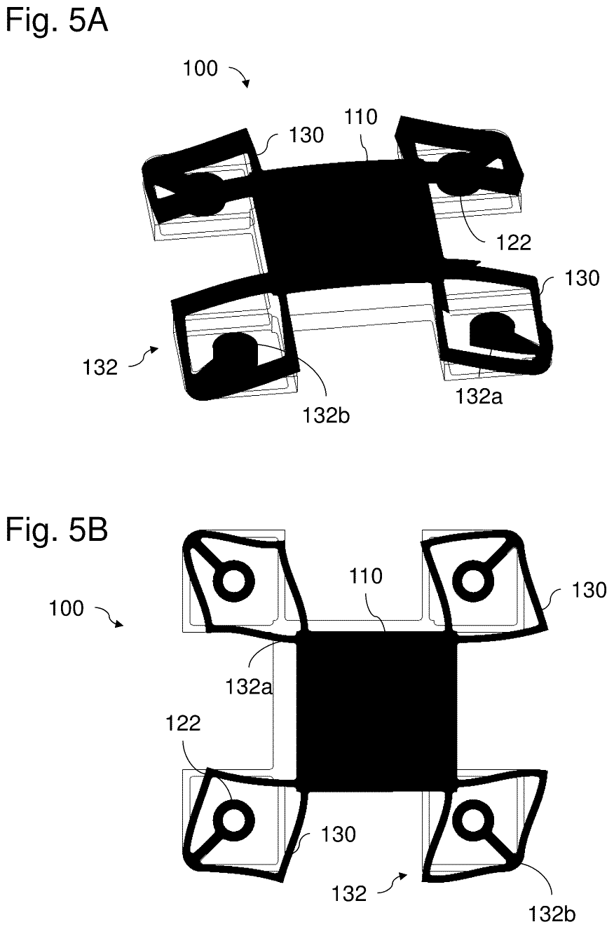

FIGS. 5A and 5B show schematic representations of vibrations of a carrying apparatus; and

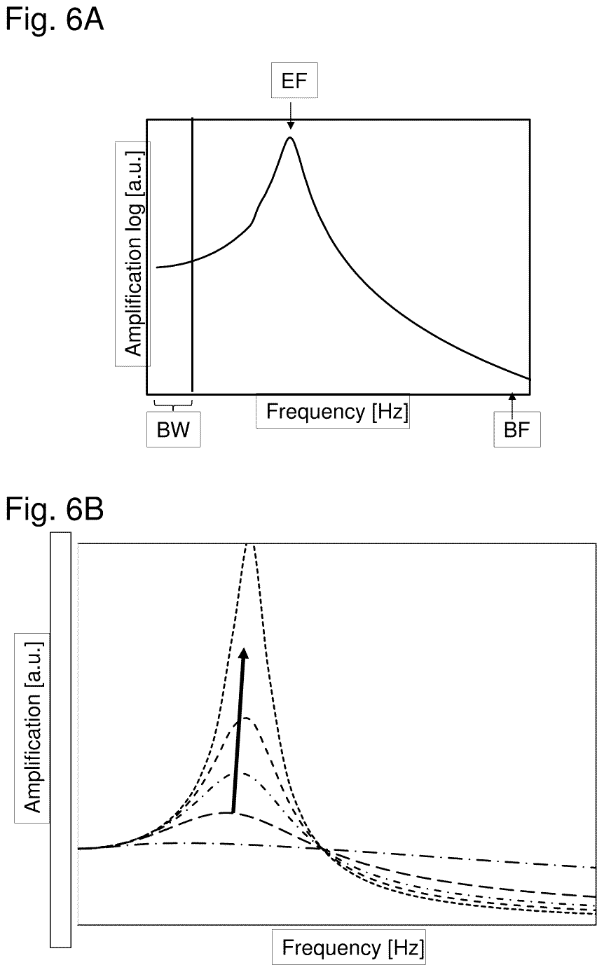

FIGS. 6A and 6B show schematic frequency diagrams.

FIG. 1 shows a schematic representation of a carrying apparatus 100, which is suitable for carrying a microelectromechanical, MEMS, sensor 200, e.g., an acceleration or rotation rate sensor. The carrying apparatus 100 has a carrier platform 110 on which the MEMS sensor 200 can be arranged or fastened. In addition, the carrying apparatus includes a coupling structure 120, which has individual, macroscopic springs 130 connected to the carrier platform 110. The coupling structure 120 can be connected to a housing structure 300, which is suitable for enclosing the carrying apparatus 100 and the MEMS sensor 200 carried by said carrying apparatus.

The carrier platform 110 can, in this case, have any shape that, on one hand, enables a MEMS sensor 200 to be mounted thereon. In particular, the MEMS sensor 200 is to be mountable on the carrier platform 110 in such a way that it follows the movements of the carrier platform 110. On the other hand, the carrier platform 110 must be kept away from surrounding components and, in particular, the housing structure 300 by the coupling structure 120 in such a way that the carrier platform 110 can vibrate unhindered, mediated by the springs 130 of the coupling structure. Preferably, the carrier platform 110 is designed plate-shaped, as this facilitates fabrication. However, carrier platforms 110 with a complex three-dimensional shape are also conceivable if this is advantageous.

The carrier platform 110 merges into the coupling structure 120 or is connected to it. As depicted in FIG. 1, the coupling structure 120 can essentially consist of springs 130, which connect the carrier platform 110 to the housing structure 300. However, the coupling structure 120 can also include further elements, such as struts, anchors, fastening points and the like, which can serve to stabilize the movements of the carrier platform 110 and/or facilitate connection to the housing structure 300 or other components of a sensor apparatus 400.

The springs 130 inserted into the coupling structure 120 are essentially characterized in that they have macroscopic dimensions, i.e., they are visible to the naked eye, for example, or have minimum dimensions of more than 0.3 mm, 0.5 mm, 1 mm or 5 mm. As a result, fabrication of the springs 130 is made significantly easier compared to micromechanical springs. In addition, the use of springs instead of elastomers reduces the risk of aging effects or altered spring characteristics in case of temperature changes. In addition, the macroscopic springs 130 can be detached relatively easily from the housing structure 300 in case of a defect in the carrying apparatus 100 or the MEMS sensor 200.

In principle, the springs 130 can be made of any material that is sufficiently elastic and dimensionally stable for this purpose. I.e., the springs 130 must be able to hold the carrier platform 110 together with the MEMS sensor 200 freely above the housing structure 300 and cushion movements of the housing structure 300 in such a way that the MEMS sensor 200 is moved as little as possible or as slowly and evenly as possible, and at the same time there is no contact with other components in the housing structure 300 or with the housing structure 300 itself. The shape of the springs 130 shown in FIG. 1 is to be understood here purely symbolically. For example, the springs 130 can be in the form of bending beam springs that extend in one direction in the form of a thin strip. Examples of this will be discussed further below. However, the springs 130 can also have any other form that can fulfill the above-mentioned functions.

In particular, the springs 130 can be made of metal. Preferably, the remainder of the coupling structure 120 is also made of a (the same or a different) metal. On one hand, metal has the above-mentioned properties of sufficient elasticity and dimensional stability. In addition, metal can easily be used to manufacture macroscopic springs, in particular bending beam springs. In this process, the metal can be brought into the desired shape in any manner known per se, e.g., by machining, eroding, punching, bending and the like. By using metal, springs 130 can be fabricated with low damping. This improves the decoupling of housing structure 300 and MEMS sensor 200, since movements of the housing structure 300 can be absorbed more easily by springs 130 with low damping and since vibrations of the springs 130 are suppressed at the operating frequency of the MEMS sensor 200.

With an appropriate configuration, the coupling structure 120 can thermally insulate the MEMS sensor 200 and the housing structure 300 from each other, i.e., temperature changes of the housing structure 300 are not transmitted to the carrier platform 110 or the MEMS sensor 200 fixed thereon, or only to a small extent. As a result, the MEMS sensor 200 is largely kept at the same temperature or temperature changes occur at least slowly and evenly. This improves the reliability of the data output by the MEMS sensor 200.

In particular, the springs 130 can have a small cross section compared to their length and form the only continuous connection consisting of one material between the housing structure 300 and the carrier platform 110. As a result, the material cross section available for heat transfer is small compared to the distance to be bridged. The result is that a flat temperature gradient will appear along the springs 130, which will not result in a significant temperature change in the MEMS sensor 120.

Alternatively or additionally, the carrier platform 110 can be designed as a heat reservoir that has a large thermal mass or heat capacity compared to the thermal mass of the coupling structure 120 (and/or has a greater mass than the coupling structure 120). The amount of heat transferred by the coupling structure 120 can then be absorbed by the carrier platform 110 without causing significant temperature changes. In this way, the temperature of the MEMS sensor 200 can be largely decoupled from the temperature of the housing structure 300.

The coupling structure 120 can be connected detachably to the housing structure 300, e.g., by means of screw connections 122 or the like. For this purpose, the coupling apparatus 120 has connection points adjacent to the springs 130, e.g., drilled holes for the insertion of screws or bolts or also plug connectors that can be inserted by means of a press fit. Due to such detachable connections, the macroscopic coupling structure 120 together with the carrier platform 110 and the MEMS sensor 200 seated thereon can be detached from the housing structure 300 if, for example, the MEMS sensor 200 or a component of the carrying apparatus 100 has become defective.

Examples of such carrying apparatuses 100 are shown in FIGS. 2, 3A and 3B. In these examples, the carrier platform 110 is designed as a plate to which the MEMS sensor 200 is attached. The MEMS sensor 200, for example, can be glued, plugged or soldered to the carrier platform 200 together with its packaging, i.e., its primary protective cover. The carrier platform 110 consists preferably of a metal.

The springs 130 are formed as pairs 132 of bending beam springs, which also consist of a metal. The carrier platform 110 and the springs 130 can consist of the same or different materials. They can be designed as a single component, i.e., integrally with each other, or can be joined together following their individual fabrication. In this case, the metal bending beam springs serve, on one hand, to provide mechanical decoupling, i.e., to cushion movement. On the other hand, they also thermally decouple the MEMS sensor 200 from external components, as described above.

In the examples of FIGS. 2 and 3A, the bending beam springs of a pair 132 are connected to a point on the circumference of the plate at their first end 132a and to each other at their second end 132b. Each of the bending beam springs is curved in such a way that there is an interspace between each pair 132 of bending beam springs. As a result, the springs 130 can absorb external movements in a symmetrical manner. In addition, such a construction increases the stability of the coupling apparatus 120, since the springs 130 of a pair 132 support each other.

FIG. 3B shows an example that is deviating in that the pairs of springs 132 do not all act upon the carrier platform 110, but that a frame 124 is present. One set of spring pairs 132 connects the carrier platform 110 to the frame 124, while another set of spring pairs 132 connects the frame 124 to the outside. It is understood that these examples can be varied arbitrarily. Thus, a different number of springs, individual springs, multiple frames, open frames, interposed springs and the like can be used to connect the carrier platform 110 to the housing structure 300.

In the examples of FIGS. 2 and 3A, the pairs 132 of bending beam springs can each be connected to the housing structure 300 via their second end 132b, preferably by means of screw connections 122 or other detachable connections. In the example of FIG. 3B, the connections to the housing structure are only present in the outer set of pairs of springs 132.

As shown in FIG. 2, the springs 130 or the coupling structure 120 can act symmetrically upon the corners of a rectangular or square carrier platform 110. Alternatively, as shown in FIGS. 3A and 3B, they can also act upon transverse sides. In this case, as shown in FIG. 2, the screw connection 122 can be located within the interspace between a pair 132 of bending beam springs, whereby a compact structure can be achieved. A symmetrical, centered arrangement is recommended in this case, as is also shown in FIG. 2. However, as shown in FIGS. 3A and 3B, the connection points can also be located outside this interspace. Here, too, a symmetrical arrangement is recommended.

With the carrying apparatuses 100 shown in FIGS. 2, 3A and 3B, a MEMS sensor fastened to the carrying apparatus 100 can be decoupled both mechanically and thermally as described above.

The carrying apparatus 100 and the MEMS sensor 200 are usually parts of a sensor apparatus 400 which, in addition to the MEMS sensor 200 and the carrying apparatus 100 as described above, also includes the housing structure 300 which encloses the carrying apparatus 100 and the MEMS sensor 200 carried thereon and is connected to the MEMS sensor 200 via the coupling structure 120 of the carrying apparatus 100.

An example of the basic structure of such a sensor apparatus 400 is shown in FIG. 4. Here, the carrying apparatus 100 from the example in FIG. 2 is fastened in a housing structure 300 by means of screws. The coupling structure 120 together with the springs 130 and the carrier platform 110 are mounted by the screws at a distance from the wall of the housing structure 300. As a result, they can vibrate both parallel to the wall of the housing structure 300 and perpendicular to this wall. Exaggerated examples of such vibrations are depicted in FIGS. 5A and 5B. The sensor apparatus 400 can also have damping means for limiting/damping the vibration, if required. For example, maximum deflections can be limited by stoppers. The housing structure 300 can also be filled with a damping gas.

In such a sensor apparatus 400, it is recommended that the coefficients of thermal expansion of at least two interconnected elements from the list of springs 130, carrier platform 110 and MEMS sensor 200 are matched to each other and preferably have a deviation of less than 300%, 200%, 100% or 50% from each other. Due to the fact that the coefficient of thermal expansion of the carrier platform 110 (and the springs 130) lies relatively close to that of the MEMS sensor 200, thermo-mechanical stress, which occurs directly between the MEMS sensor 200 and the carrier platform 110, can be avoided.

In particular, the carrier platform 110 and the springs 130/coupling structure 120 can be manufactured of the same metal. When selecting the metal, the coefficient of thermal expansion of the MEMS sensor 200 or its basic components will be taken into account. For example, Kovar (Fe—Ni—Co alloy) can be used for the springs 130 and/or the carrier platform 110 if the MEMS sensor 200 is made on the basis of silicon, as these materials have similar coefficients of thermal expansion. Kovar, for example, has a coefficient of thermal expansion of 5.6 ppm/K and silicon of 2.6 ppm/K. Aluminum has a coefficient of thermal expansion of 23 ppm/K, i.e., about 1000% of the value of silicon. An elastomer/silicone, for example, can have 200 ppm/K and thus approx. 10000% of the value of silicon.

For weight reasons, it can often be advantageous to fabricate the housing structure 300 from aluminum, while the MEMS sensor 200 is based on silicon. The carrying apparatus 100 has then the task of absorbing deformations of the housing under temperature due to the coefficient of thermal expansion and not passing them on to the MEMS sensor 200. It must create an environment for the MEMS sensor 200 that is as stress and deformation-free as possible. At the same time, it is important that the coefficient of thermal expansion of the carrying apparatus 100 is matched to the coefficient of thermal expansion of the MEMS sensor 200, since otherwise stress would occur between the carrying apparatus 100 and the MEMS sensor 200.

Due to the fact that the thermal deformations of the housing structure 300 by the springs 130 absorb/compensate for the deformation relative to the chip, the coefficient of thermal expansion of the housing structure 300 plays only a subordinate role. The choice of material for the housing structure 300 is therefore arbitrary in this respect. What is more important here is that the coefficient of thermal expansion of the carrier platform 110 (and the springs 130) lies relatively close to that of the MEMS sensor 200, as otherwise thermo-mechanical stress would occur directly between the chip and the carrier platform 110.

By adjusting the coefficients of thermal expansion, deformations due to different changes in length can be avoided. This prevents changes in the position of the carrier platform 110 and thus of the MEMS sensor 200 in case of temperature changes, whereby the reliability of the sensor apparatus 400 is improved.

The carrying apparatus 100 can be designed in such a way that its natural frequency with the MEMS sensor 200 attached thereto is greater than the bandwidth of the MEMS sensor 200 that can be achieved with the sensor apparatus 400 and is less than the drive frequency of the MEMS sensor 200 used in the sensor apparatus 400. In particular, this can be achieved by adjusting the masses of the coupling device 120 and the carrier platform 110, as well as by adjusting the spring hardness of the springs 130.

The carrying apparatus 100 then exhibits a vibration behavior as, for example, shown in FIG. 6A. Here, the operating or drive frequency BF of the MEMS sensor 200 is comparatively high, e.g., in the range of 10 kHz. The bandwidth BW of the MEMS sensor 200, i.e., the frequency range accessible for measurements, is comparatively low, e.g., in the range from 10 to 100 Hz. The natural and/or resonant frequency (frequencies) EF of the carrying apparatus 100 together with the MEMS sensor 200 lie in between, with especially the operating frequency BF being significantly higher. As a result, it is ensured that resonances or natural vibrations of the carrying apparatus 100 integrated into the sensor apparatus 400 do not impair either the drive of the MEMS sensor 200 or the measuring range of the sensor apparatus 400. The reliability of the sensor apparatus 400 is also increased hereby. At the same time, this ensures that the operating frequency of the MEMS sensor 200 is as well insulated as possible, so that vibrations from outside have no impact on the sensor performance.

FIG. 6B shows, in this case, how the amplification of the spring vibrations, i.e., the ability to absorb vibrations, changes depending on the damping. The arrow in FIG. 6B indicates decreasing damping. In case of lower damping, vibrations close to the natural frequency couple more strongly. At the same time, frequencies close to the operating frequency BF are also suppressed with lower damping. Low damping, as can be achieved by means of metal springs, for example, is therefore advantageous.

In this case, the carrying apparatus 100 ideally has a natural or resonant frequency that is identical in all three spatial directions. For carrying apparatuses such as those shown in FIGS. 2, 3A and 3B, which have a structure that is essentially two-dimensional, this can be achieved on one hand by choosing a symmetrical structure. The mass ratios are then adjusted in such a way that an identical natural/resonant frequency also results in the third spatial direction. Corresponding vibrations of the carrying apparatus 100 shown in FIGS. 2 and 4 are shown in FIGS. 5A and 5B.

A carrying apparatus 100 that reacts in the same way to excitations in three spatial directions avoids the need to take preferred directions into account when using the sensor apparatus 400, especially when aligning it. As a result, the correct use of the sensor apparatus 400 is simplified, which, in turn, leads to increased reliability of the data from the sensor apparatus 400.

In the sensor apparatus 400, the carrying apparatus 100 can, in addition, be suitable for preventing transmission of deformations of the housing structure 300, in particular due to temperature changes, to the MEMS sensor 200. For this purpose, the carrying apparatus 100 can be suspended in such a way that deformations of the housing structure 300 lead to a compression of the springs 130, but without this significantly changing the position of the MEMS sensor 200 or so that no mechanical stress is transferred to the MEMS sensor. In addition, deformations due to temperature changes are also usually symmetrical in a symmetrical structure and can be compensated for by shaping the carrying apparatus 100 symmetrically, e.g., by compressing or expanding all springs 130 equally. As a result, the position of the MEMS sensor 200 in space changes as little as possible, whereby influences on the measurements of the MEMS sensor 200 remain low. This also increases the reliability of the sensor apparatus 400.

With the means described above, a MEMS sensor 200 can be reliably and easily decoupled from movements of neighboring components. This improves the reliability of the MEMS sensor 200 or a sensor apparatus 400 including the MEMS sensor 200.

1. A sensor apparatus, including
a microelectromechanical, MEMS, sensor;
a carrying apparatus, which carries the MEMS sensor; and
a housing structure, which encloses the carrying apparatus and the MEMS sensor carried thereon; wherein
the carrying apparatus includes:
a carrier platform, which carries the MEMS sensor; and
a coupling structure, which has individual, macroscopic springs connected to the carrier platform and is connected to the housing structure.

2. The sensor apparatus according to claim 1, wherein
at least the springs, preferably the entire coupling structure, are made of a metal.

3. The sensor apparatus according to claim 1, wherein
the coupling structure is connected to the housing structure by means of screw connections.

4. The sensor apparatus according to claim 1, wherein
the coupling structure thermally insulates the MEMS sensor and the housing structure from each other, preferably in that the springs have a small cross section compared to their length, and the springs are the only continuous connection consisting of one material between the housing structure and the carrier platform and/or in that the thermal mass of the coupling structure is less than the thermal mass of the carrier platform.

5. The sensor apparatus according to claim 1, wherein
the carrier platform is designed as a plate;
the springs are formed as pairs of bending beam springs, wherein the bending beam springs of a pair are connected to a point on the circumference of the plate at their first end and to each other at their second end, and each bending beam spring is curved in such a way that there is an interspace between each pair of bending beam springs; and
the pairs of bending beam springs are each connected to the housing structure via their second end, preferably by means of screw connections.

6. (canceled)

7. The sensor apparatus according to claim 1, wherein
the coefficients of thermal expansion of at least two interconnected elements from the list of springs, carrier platform, MEMS sensor are matched to each other and preferably have a deviation of less than 300%, 200%, 100% or 50% from each other.

8. The sensor apparatus according to claim 7, wherein
the natural frequency of the carrying apparatus with the MEMS sensor attached thereto is greater than the bandwidth of the MEMS sensor and is less than the drive frequency of the MEMS sensor.

9. The sensor apparatus according to claim 8, wherein
the carrying apparatus has a resonant frequency that is identical in all three spatial directions.

10. The sensor apparatus according to claim 9, wherein
the carrying apparatus is suitable for preventing transmission of deformations of the housing structure, in particular due to temperature changes, to the MEMS sensor.
